(19) United States
(12) Patent Application Publication
(10) Pub. No.: US 2012/0256744 A1
(43) Pub. Date: Oct. 11, 2012

(54) DISPLAY WITH FUNCTION OF DARK SHINING AND CURRENCY IDENTIFIER

(75) Inventor: XU-BIAO CHEN, Fuqing (CN)

(73) Assignee: TPV Electronics (Fujian) Co., Ltd., Fuqing City (CN)

(21) Appl. No.: 13/082,390

(22) Filed: Apr. 7, 2011

(51) Int. Cl. G08B 21/00; G01J 5/10; G01R 33/02; G01F 23/00

(52) U.S. Cl. 340/540; 250/358.1; 250/338.1; 324/244; 356/71

(57) ABSTRACT

A display with function of dark shining and currency identifier is provided. The display comprises a micro controller, a button unit and an ultraviolet emitter. The button unit contains an ultraviolet button, and the button unit might output an ultraviolet signal (S_{UV}) to the micro controller if the ultraviolet button is pressed. The ultraviolet emitter connects to the micro controller, and the micro controller may receive the ultraviolet signal (S_{UV}) so as to drive the ultraviolet emitter to emit ultraviolet light. Whereby, the display may achieve function of dark shining and currency identifying by means of the ultraviolet light.

### FIELD OF THE INVENTION

The present invention relates to a display, particularly to a display with function of dark shining and currency identifier.

### DESCRIPTION OF THE PRIOR ART

In recent year, due to the cheaper and cheaper price of the Liquid Crystal Display (LCD), the monitor has gradually come into vogue in home TV and computer display. Besides, because of its thinness and light characters comparative to cathode-ray-tube television, the LCD has become more and more favorable and thus easily seen in public such as station, hospital, convenient store or theater. Those LCDs not only can be utilized to deliver message, but also can achieve some advertising purpose. Therefore, the usage and application of LCD will be wider and wider.

One application of the LCD is to be utilized in grocery store and supermarket for the purpose of presenting message and advertisement. After selling, the store owner always has the currency examined by a currency identifier, so as to prevent from receiving the counterfeit money. In practical condition, the LCD and the currency identifier are vital and critical for those stores. However, the display and the currency identifier are both space-consumed, and therefore it is not convenient for some of those stores which only have little room.

Moreover, having one LCD and one currency identifier on hand is also wasted. Still, the paper money sometimes can not be clearly seen or recognized if the room is dim, and so that the chance of receiving fake money or the condition of countering bill with error are absolutely increased.

Therefore, how to incorporating the function of currency identifier, dark shining and display into a LCD, so as to decrease the business cost and save the store's space, is a critical problem needed to be settled.

### SUMMARY OF THE INVENTION

The primary object of present invention is to incorporate the currency identifier, dark shining and display into a LCD, so as to decrease the business cost and save the store's space.

To achieve the foregoing and other objects, a display with function of dark shining and currency identifier is provided. The display comprises a micro controller, a button unit and an ultraviolet emitter. The button unit contains an ultraviolet button, and the button unit might output an ultraviolet signal (S_{UV}) to the micro controller if the ultraviolet button is pressed. The ultraviolet emitter connects to the micro controller, and the micro controller may receive the ultraviolet signal (S_{UV}) so as to drive the ultraviolet emitter to emit ultraviolet light. Whereby, the display may achieve function of dark shining and currency identifying by means of the ultraviolet light.

In the aforementioned display, wherein the display further contains a lighting unit and a magnetism detector, the button unit further containing a first sensing button and the micro controller having at least one magnetism distributive data loaded, so that the button unit might output a first signal (S₁) to the micro controller so as to drive the magnetism detector to sense the magnetic distributive condition surrounded and to distinguish whether the magnetic distributive condition matches the magnetism distributive data when the first sensing button is pressed, and then the micro controller accordingly outputs a revealing signal (S_{DIS}) to the lighting unit; wherein the lighting unit comprises a first lamp and a second lamp, the revealing signal (S_{DIS}) being able to drive the first lamp to radiate if the micro controller verifies that the data matches the condition, the revealing signal (S_{DIS}) being able to drive the second lamp to radiate if the micro controller verifies that the data does not match the condition.

In the aforementioned display, wherein the first lamp is Light Emitting Diode (LED) or the second lamp is LED.

In the aforementioned display, wherein the lighting color of the first lamp is different from the lighting color of the second lamp.

In the aforementioned display, wherein the display further contains a lighting unit and a magnetism detector, the button unit further containing a first sensing button and the micro controller having at least one magnetism distributive data loaded, so that the button unit might output a first signal (S₁) to the micro controller so as to drive the magnetism detector to sense the magnetic distributive condition surrounded and to distinguish whether the magnetic distributive condition matches the magnetism distributive data when the first sensing button is pressed, and then the micro controller accordingly outputs a revealing signal (S_{DIS}) to the lighting unit; wherein the lighting unit is On Screen Display (OSD), the lighting unit being able to present a consistent message if the micro controller verifies that the data matches the condition, and the lighting unit being able to present a non-consistent message if the micro controller verifies that the data does not match the condition.

In the aforementioned display, wherein the consistent message might contain text, photo or diagram, and the non-consistent message might contain text, photo or diagram.

In the aforementioned display, wherein the display further comprises a lighting unit, a infrared emitter and a infrared receiver; the button unit containing a second sensing button and the micro controller having at least one infrared image distributive data loaded, so that the button unit might output a second signal (S₂) to the micro controller so as to drive the infrared emitter to emit infrared ray when the second sensing button is pressed; the infrared receiver being able to receive the infrared image distributive condition of an examined object and then the micro controller simultaneously distinguishing whether the infrared image distributive condition matches the infrared image distributive data so that a revealing signal (S_{DIS}) might be accordingly outputted to the lighting unit; wherein the lighting unit comprises a first lamp and a second lamp, the revealing signal (S_{DIS}) being able to drive the first lamp to radiate if the micro controller verifies that the data matches the condition, the revealing signal (S_{DIS}) being able to drive the second lamp to radiate if the micro controller verifies that the data does not match the condition.

In the aforementioned display, wherein the first lamp is Light Emitting Diode (LED) or the second lamp is LED.

In the aforementioned display, wherein the lighting color of the first lamp is different from the lighting color of the second lamp.

In the aforementioned display, wherein the display further comprises a lighting unit, a infrared emitter and a infrared receiver; the button unit containing a second sensing button and the micro controller having at least one infrared image distributive data loaded, so that the button unit might output a second signal (S₂) to the micro controller so as to drive the infrared emitter to emit infrared ray when the second sensing button is pressed; the infrared receiver being able to receive the infrared image distributive condition of an examined object and then the micro controller simultaneously distinguishing whether the infrared image distributive condition matches the infrared image distributive data so that a revealing signal (S_{DIS}) might be accordingly outputted to the lighting unit; wherein the lighting unit is On Screen Display (OSD), the lighting unit being able to present a consistent message if the micro controller verifies that the data matches the condition, and the lighting unit being able to present a non-consistent message if the micro controller verifies that the data does not match the condition.

In the aforementioned display, wherein the consistent message might contain text, photo or diagram, and the non-consistent message might contain text, photo or diagram.

Whereby, the display of present invention may incorporate the function of currency identifier and dark shining, so as to decrease the business cost and save the store's space, and then achieve practicability and convenience.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A is front view diagram of the display according to the first embodiment of present invention;

FIG. 1B is side view diagram of the display according to the first embodiment of present invention;

FIG. 1C is functional block diagram of the display according to the first embodiment of present invention;

FIG. 2A is diagram of lighting unit according to the second embodiment of the display when the match is sensed;

FIG. 2B is diagram of lighting unit according to the second embodiment of the display when the non-match is sensed.

### DESCRIPTION OF THE PREFERRED EMBODIMENTS

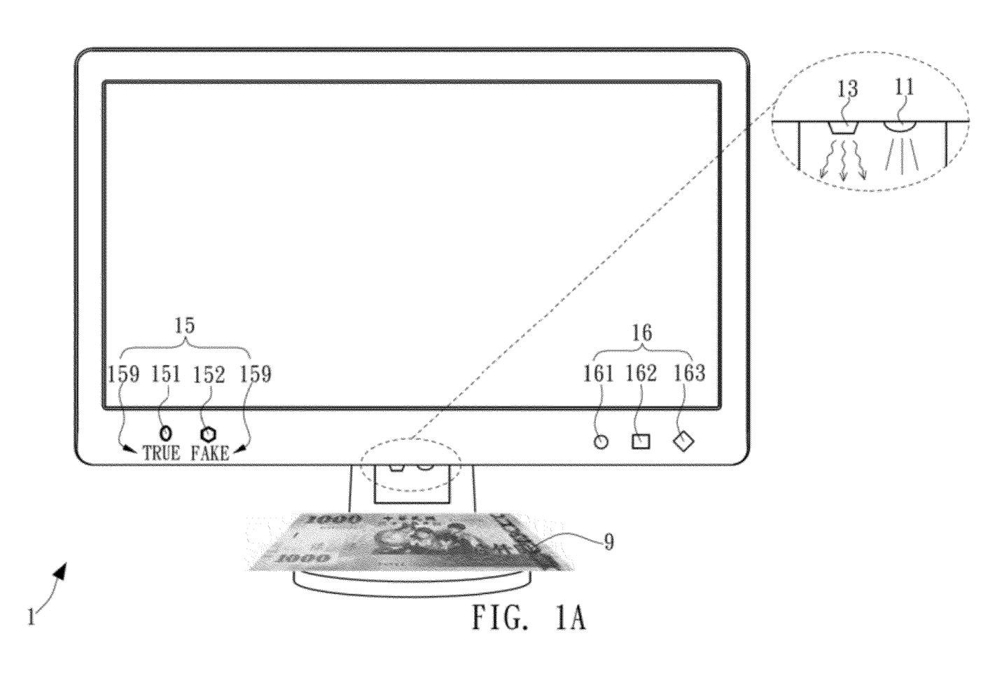

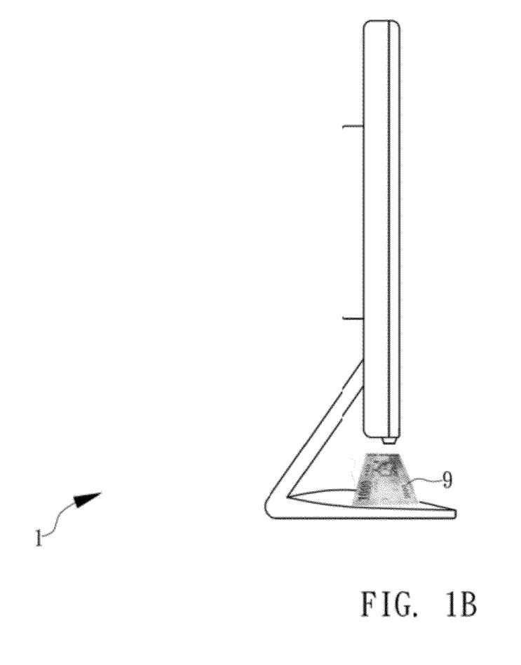

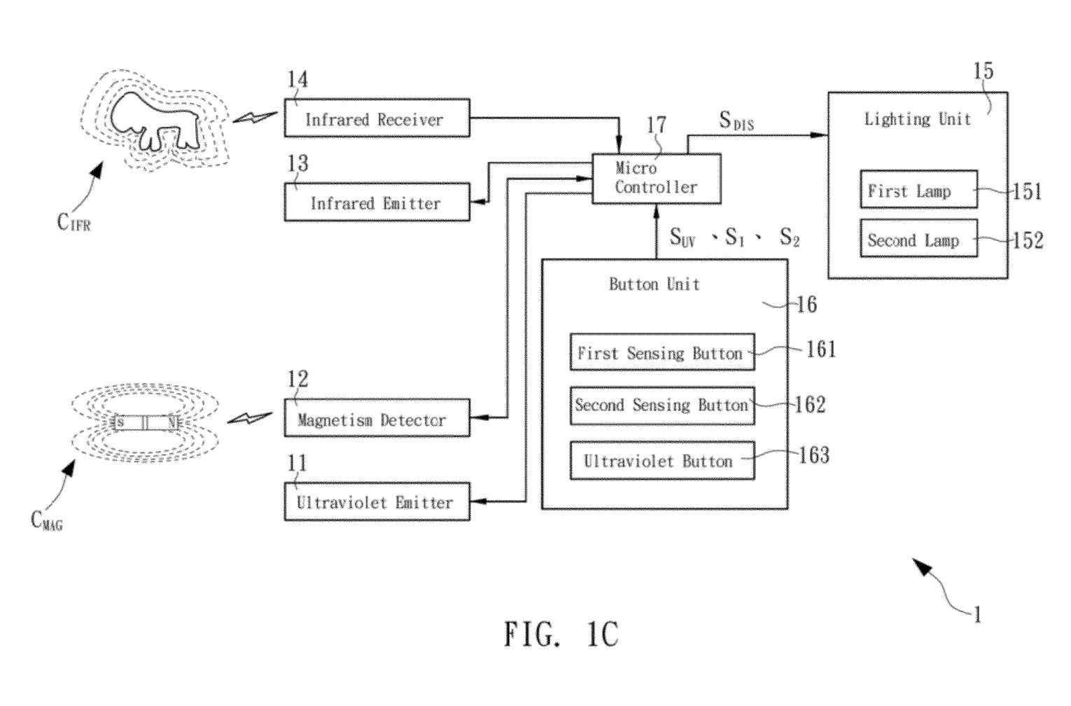

Please refer to FIG. 1A˜1C simultaneously, FIG. 1A is front view diagram of the display according to the first embodiment of present invention, FIG. 1B is side view diagram of the display according to the first embodiment of present invention, FIG. 1C is functional block diagram of the display according to the first embodiment of present invention. As shown in FIG. 1A˜1C, a display 1 comprises a micro controller 17, a button unit 16, an ultraviolet emitter 11, a lighting unit 15, a magnetism detector 12, an infrared emitter 13 and an infrared receiver 14. The button unit 16, the ultraviolet emitter 11, the lighting unit 15, the magnetism detector 12, the infrared emitter 13 and the infrared receiver 14 are respectively connected to the micro controller 17. The button unit 16 contains an ultraviolet button 163, a first sensing button 161 and a second sensing button 162; as shown in FIG. 1A, the ultraviolet button 163, the first sensing button 161 and the second sensing button 162 are disposed at lower right corner of the display 1, so as to be conveniently pressed by human. The lighting unit 15 contains a first lamp 151 and a second lamp 152. The first lamp 151 and the second lamp 152 are both disposed at lower left corner of the display 1, so as to be easily read the illumination of the first lamp 151 and the second lamp 152. In preferable embodiment, the first lamp 151 or the second lamp 152 might be Light Emitting Diode (LED), and the color of both lamps are distinct. The ultraviolet emitter 11 and the infrared emitter 13 are both disposed at lower edge of the display 1. As shown in FIG. 1C, if the ultraviolet button 163 is pressed, the button unit 16 might output an ultraviolet signal (S_{UV}) to the micro controller 17. The micro controller 17 may receive the ultraviolet signal (S_{UV}), so as to drive the ultraviolet emitter 11 to emit ultraviolet light. Normally, the ultraviolet light emitted is around 365 nm.

In order to conquer the problem and drawback, the function of currency identifier and dark shining may be integrated into the display 1. When the display 1 of present invention is utilized, an examined object 9 (shown in FIG. 1B and 1C) may be detected by the ultraviolet light, so as to differentiate the paper money; wherein the examined object 9 is absolutely paper money needed to be sensed. In practice, the paper money is normally coated by specific image with fluorescent agent, so that the function of currency identifier could be easily carried out. In this manner, the fluorescent agent may shine under the ultraviolet light and then the image is thus revealed. On the contrary, the fluorescent agent can not shine under visual light. When the paper money with fluorescent agent is exposed under the ultraviolet light, a blue light with wavelength of 420˜460 nm is stimulated and thus the blue light can be seen, so as to distinguish the currency if the paper money is true. Therefore the display 1 of present invention may have function of currency identifier by means of the ultraviolet light.

However, it might not be enough for present invention, because of that better counterfeit technology is always developed. Therefore, the display 1 of present invention further increases several anti counterfeit technologies and improves the accurate of recognizing by means of magnetic technology. In some countries, the paper money is coated with magnetic ink, so as to avoid the flood of counterfeit money. In this manner, those paper money with magnetic ink coated have magnetic distributive condition surrounded the paper money. In order to detect the magnetic distributive condition, the micro controller 17 has at least one magnetism distributive data loaded, wherein the number of the magnetism distributive data is equal to the type of the paper money. Namely, if the detected paper money has 4 kinds of face value, e.g. 50 dollar, 100 dollar, 500 dollar and 1000 dollar, then the micro controller 17 needs to have 4 respective magnetism distributive data loaded previously. Please refer to FIG. 1C, when the first sensing button 161 is pressed, the button unit 16 outputs a first signal (S₁) to the micro controller 17, so as to drive the magnetism detector 12 to sense the magnetic distributive condition (C_{MAG}) surrounded the paper money, and then to distinguish whether the magnetic distributive condition (C_{MAG}) matches the magnetism distributive data of previous 4 paper money. Afterward, according to the matching result, the micro controller 17 correspondingly outputs a revealing signal (S_{DIS}) to the lighting unit 15. When the result is match, the revealing signal (S_{DIS}) drives the first lamp 151 to radiate; when the result is not match, the revealing signal (S_{DIS}) drives the second lamp 152 to radiate. Since the colors of the first lamp 151 and the second lamp 152 are distinct, it is obvious that the authenticity of the paper money can be therefore distinguished by means of the illuminating lamp color. In this manner, the examined object 9, i.e. paper money, can be recognized after the magnetic ink of the paper money is sensed by means of the magnetism detector 12. As a result, the display 1 may further have function of dark shining and currency identifier with accurate efficiency.

Additionally, the currency may be more efficiently distinguished by means of infrared image technology. Normally the paper money is composed of specific paper material, which is printed with multi layers of ink, and thus raises difficulty for counterfeit. For physical reason, different material, different ink or different thickness of printing may result in different absorption or penetrability to infrared. In this manner, if a piece of paper money has exact identical absorption and penetrability to infrared, then it is nearly positive for the its authenticity. In present invention, the display 1 may utilize this principle. Preferably, the micro controller 17 has at least one infrared image distributive data loaded, wherein the number of the infrared image distributive data is equal to the type of the paper money. Namely, if the detected paper money has 3 kinds of face value, e.g. 10 dollar, 200 dollar, and 500 dollar, then the micro controller 17 needs to have 3 respective infrared image distributive data loaded previously. In this manner, as shown in FIG. 1C, when the second sensing button 162 is pressed, the button unit 16 might immediately output a second signal (S₂) to the micro controller 17, so that the micro controller 17 may drive the infrared emitter 13 to emit infrared ray. When the infrared ray penetrates the examined object 9 (i.e. paper money), the infrared receiver 14 could immediately receive the infrared image distributive condition (C_{IFR}) of the examined object 9. In the meanwhile, the micro controller 17 could simultaneously distinguish whether the infrared image distributive condition (C_{IFR}) matches any one of aforementioned three infrared image distributive data. By means of the distinguishing, a revealing signal (S_{DIS}) might be accordingly outputted from the micro controller 17 to the lighting unit 15, and thus the first lamp 151 or the second lamp 152 could illuminate.

Preferably, the distinguishing is read by means of colors of the first lamp 151 and the second lamp 152. In other embodiment, as shown in FIG. 1A, the color of the first lamp 151 and the second lamp 152 is the same. Therefore, some labels 159 are needed to be marked near the first lamp 151 and the second lamp 152, so that people may know the meaning of those lamps. Also, the first lamp 151 and the second lamp 152 could be designed with different shapes or different configuration, so as to be easily distinguished by people. Thus the aforementioned function of currency identifier still could be achieved.

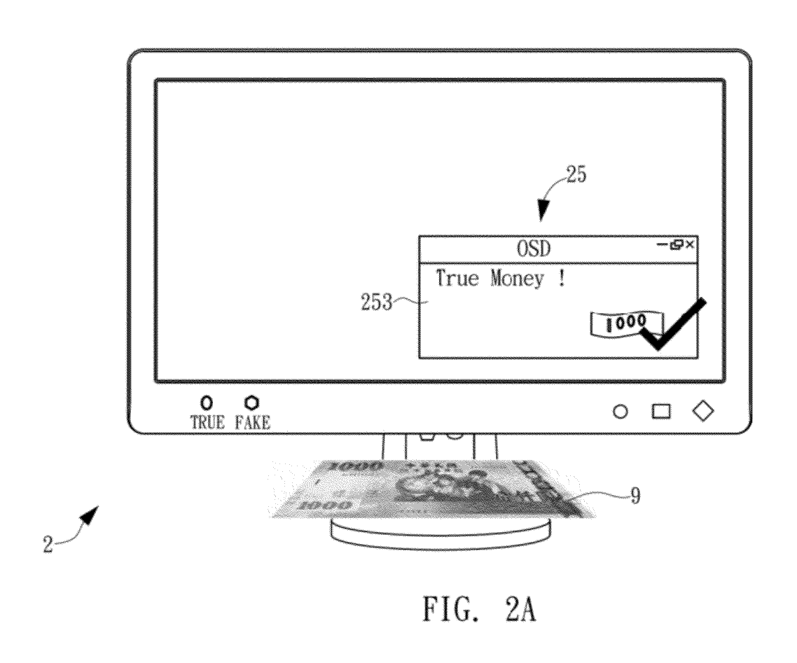

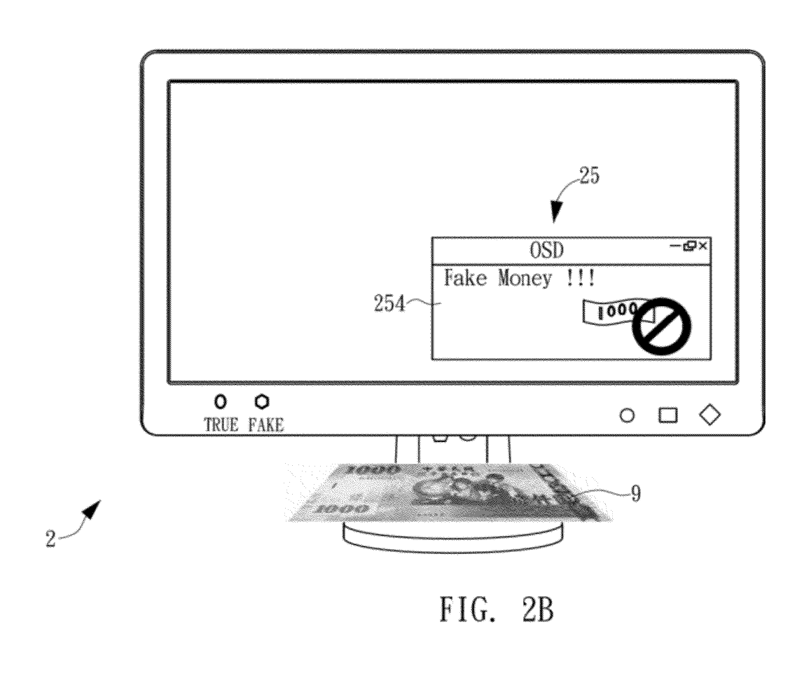

The aforementioned lighting unit could be composed of LED; however, those skilled in the art might replace the LED by software, e.g. On Screen Display (OSD). Please refer to FIG. 2A and FIG. 2B, FIG. 2A is diagram of lighting unit according to the second embodiment of the display when the match is sensed; FIG. 2B is diagram of lighting unit according to the second embodiment of the display when the non-match is sensed. As shown in the FIG. 2A, when the micro controller of the display 2 verifies that the data matches the condition (no matter ultraviolet, magnetic or infrared way), it means that the examined object 9 is true money and thus the lighting unit 25 may reveal a consistent message 253; wherein the consistent message 253 could contain text, photo or diagram. As shown in FIG. 2B, when the micro controller of the display 2 verifies that the data does not match the condition, it means that the examined object 9 is fake money and thus the lighting unit 25 may present a non-consistent message 254; wherein the non-consistent message 254 could also contain text, photo or diagram.

Summarily, the display according to present invention may incorporate several functions including currency identifier, dark shining and video displaying, so that the business cost is decreased and the store's space is saved, and thus the practicability and convenience are therefore achieved.

While certain exemplary embodiments have been described and shown in the accompanying drawings, it is to be understood that such embodiments are merely illustrative of and not restrictive on the broad invention, and that this invention is not be limited to the specific constructions and arrangements shown and described, since various other modifications may occur to those ordinarily skilled in the art.

I claim:

1. A display with function of dark shining and currency identifier, comprising:
a micro controller;
a button unit containing an ultraviolet button, the button unit might output an ultraviolet signal (S_{UV}) to the micro controller if the ultraviolet button is pressed;
an ultraviolet emitter connecting to the micro controller, the micro controller receiving the ultraviolet signal (S_{UV}) so as to drive the ultraviolet emitter to emit ultraviolet light;
whereby the display may achieve function of dark shining and currency identifying by means of the ultraviolet light.

2. The display as claim 1, wherein the display further contains a lighting unit and a magnetism detector, the button unit further containing a first sensing button and the micro controller having at least one magnetism distributive data loaded, so that the button unit might output a first signal (S₁) to the micro controller so as to drive the magnetism detector to sense the magnetic distributive condition surrounded and to distinguish whether the magnetic distributive condition matches the magnetism distributive data when the first sensing button is pressed, and then the micro controller accordingly outputs a revealing signal (S_{DIS}) to the lighting unit.

3. The display as claim 2, wherein the lighting unit comprises a first lamp and a second lamp, the revealing signal (S_{DIS}) being able to drive the first lamp to radiate if the micro controller verifies that the data matches the condition, the revealing signal (S_{DIS}) being able to drive the second lamp to radiate if the micro controller verifies that the data does not match the condition.

4. The display as claim 3, wherein the first lamp is Light Emitting Diode (LED) or the second lamp is LED.

5. The display as claim 3, wherein the lighting color of the first lamp is different from the lighting color of the second lamp.

6. The display as claim 2, wherein the lighting unit is On Screen Display (OSD), the lighting unit being able to present a consistent message if the micro controller verifies that the data matches the condition, and the lighting unit being able to present a non-consistent message if the micro controller verifies that the data does not match the condition.

7. The display as claim 6, wherein the consistent message might contain text, photo or diagram, and the non-consistent message might contain text, photo or diagram.

8. The display as claim 1, wherein the display further comprises a lighting unit, a infrared emitter and a infrared receiver; the button unit containing a second sensing button and the micro controller having at least one infrared image distributive data loaded, so that the button unit might output a second signal (S₂) to the micro controller so as to drive the infrared emitter to emit infrared ray when the second sensing button is pressed; the infrared receiver being able to receive the infrared image distributive condition of an examined object and then the micro controller simultaneously distinguishing whether the infrared image distributive condition matches the infrared image distributive data so that a revealing signal (S_{DIS}) might be accordingly outputted to the lighting unit.

9. The display as claim 8, wherein the lighting unit comprises a first lamp and a second lamp, the revealing signal (S_{DIS}) being able to drive the first lamp to radiate if the micro controller verifies that the data matches the condition, the revealing signal (S_{DIS}) being able to drive the second lamp to radiate if the micro controller verifies that the data does not match the condition.

10. The display as claim 9, wherein the first lamp is Light Emitting Diode (LED) or the second lamp is LED.

11. The display as claim 9, wherein the lighting color of the first lamp is different from the lighting color of the second lamp.

12. The display as claim 8, wherein the lighting unit is On Screen Display (OSD), the lighting unit being able to present a consistent message if the micro controller verifies that the data matches the condition, and the lighting unit being able to present a non-consistent message if the micro controller verifies that the data does not match the condition.

13. The display as claim 12, wherein the consistent message might contain text, photo or diagram, and the non-consistent message might contain text, photo or diagram.
